(19) United States
(12) Patent Application Publication
(10) Pub. No.: US 2026/0305273 A1
(43) Pub. Date: Oct. 1, 2026

(54) Aluminum Nitride Bonding

(71) Applicant: Applied Materials, Inc., Santa Clara, CA (US)

(72) Inventors: Matthew O'LEARY, Missoula, MT (US); Kun LI, Delmar, NY (US); Keith Kwong Hon WONG, Wappingers Falls, NY (US)

(21) Appl. No.: 19/095,599

(22) Filed: Mar. 31, 2025

(51) Int. Cl. H01L 21/3105; C23C 16/34; H01L 21/02

(52) U.S. Cl. CPC H10P 95/062; H10P 14/69391; C23C 16/34

(57) ABSTRACT

Methods of preparing aluminum nitride for bonding without high temperature annealing leverage an inversion domain boundary (IDB) to form a bonding surface composed of aluminum-polar aluminum nitride. In some embodiments, the method may comprise depositing an aluminum nitride layer where at least a portion of a thickness of the aluminum nitride layer is deposited with an oxygen content of approximately three percent by mass and planarizing the aluminum nitride layer with a chemical mechanical planarization (CMP) process immediately after depositing the aluminum nitride layer and prior to a bonding process to form a bonding surface.

### FIELD

Embodiments of the present principles generally relate to semiconductor processing of semiconductor substrates.

### BACKGROUND

Aluminum nitride deposited by conventional means is not ideal for fusion bonding. The surfaces of the aluminum nitride are rough and provide little surface contact area, resulting in voids and other bonding defects. Attempts to improve the bonding surfaces by coating the surface of the aluminum nitride to smoothen the surface often result in diminished thermal conductance by the unavoidable introduction of a highly thermal resistant coating. The inventors have also observed that attempts to use chemical mechanical planarization (CMP) on aluminum nitride to smoothen the surfaces uniformly across the wafer has proven unsuccessful, as the aluminum nitride is highly sensitive to CMP processing and is substantially or completely removed during such processes.

Accordingly, the inventors have provided improved processes for increasing the resiliency of aluminum nitride to enable uniform CMP processing of the aluminum nitride to increase bonding performance.

### SUMMARY

Methods for improving bonding surfaces of aluminum nitride are provided herein.

In some embodiments, a method of bonding aluminum nitride may comprise depositing an aluminum nitride layer where at least a portion of a thickness of the aluminum nitride layer is deposited with an oxygen content of approximately three percent by mass and planarizing the aluminum nitride layer with a chemical mechanical planarization (CMP) process immediately after depositing the aluminum nitride layer and prior to a bonding process to form a bonding surface.

In some embodiments, the method may further comprise at least a portion of a thickness that is approximately 5 nm to approximately 50 nm and the thickness is approximately 100 nm to approximately 1000 nm, an aluminum nitride layer that is deposited on a silicon material with a crystal structure orientation on a deposition surface of (100), a silicon material that contains at least one semiconductor structure, an aluminum nitride layer that is deposited at a temperature of approximately 250 degrees Celsius to approximately 400 degrees Celsius, an aluminum nitride layer that is deposited using RF with a power density of approximately 5 watts per cm² to approximately 50 watts per cm², argon and nitrogen that are present during deposition of the aluminum nitride layer in an argon to nitrogen ratio of approximately 1:3 to approximately 1:5, oxygen used during deposition of at least a portion of the aluminum nitride layer that is approximately 0.5 percent to approximately 1.5 percent of gases by volume used during deposition, an aluminum nitride layer that is deposited in a process chamber using pulsed RF power, an aluminum nitride layer that has a bonding surface after the CMP process with a cross-surface nonuniformity of less than 5%, and/or an aluminum nitride layer has a full-width-half-maximum (FWHM) of approximately 2 degrees or less after deposition.

In some embodiments, a method of bonding aluminum nitride may comprise depositing a first aluminum nitride layer with an oxygen content of approximately three percent by mass on a silicon material with a crystal structure orientation on a deposition surface of (100) where the first aluminum nitride layer has a first thickness of approximately 5 nm to approximately 50 nm, depositing a second aluminum nitride layer without oxygen on the first aluminum nitride layer where the second aluminum nitride layer has a second thickness of approximately 100 nm to approximately 1000 nm, and planarizing the second aluminum nitride layer with a CMP process to form a bonding surface immediately after depositing the second aluminum nitride layer and prior to a bonding process.

In some embodiments, the method may further include a silicon material that contains at least one semiconductor structure, a first aluminum nitride layer and a second aluminum nitride layer that are deposited at a temperature of approximately 250 degrees Celsius to approximately 400 degrees Celsius, a first aluminum nitride layer and a second aluminum nitride layer that are deposited using RF with a power density of approximately 5 watts per cm² to approximately 50 watts per cm², oxygen used during deposition of the first aluminum nitride layer that is approximately 0.5 percent to approximately 1.5 percent of gases by volume used during deposition of the first aluminum nitride layer, a second aluminum nitride layer that has a bonding surface after the CMP process with a cross-surface nonuniformity of less than 5%, and/or a first aluminum nitride layer and a second aluminum nitride layer combined that has a full-width-half-maximum (FWHM) of approximately 2 degrees or less after deposition.

In some embodiments, a non-transitory, computer readable medium having instructions stored thereon that, when executed, cause a method of bonding aluminum nitride to be performed, the method may comprise depositing an aluminum nitride layer where at least a portion of a thickness of the aluminum nitride layer is deposited with an oxygen content of approximately three percent by mass and planarizing the aluminum nitride layer with a CMP process immediately after depositing the aluminum nitride layer and prior to a bonding process to form a bonding surface.

In some embodiments, the method on the non-transitory, computer readable medium may further comprise at least a portion of the thickness that is approximately 5 nm to approximately 50 nm and the thickness is approximately 100 nm to approximately 1000 nm, an aluminum nitride layer that is deposited on a silicon material with a crystal structure orientation on a deposition surface of (100) and a silicon material that contains at least one semiconductor structure, an aluminum nitride layer that is deposited at a temperature of approximately 250 degrees Celsius to approximately 400 degrees Celsius, an aluminum nitride layer that is deposited using RF with a power density of approximately 5 watts per cm² to approximately 50 watts per cm², oxygen used during deposition of at least a portion of the aluminum nitride layer that is approximately 0.5 percent to approximately 1.5 percent of gases by volume used during deposition, an aluminum nitride layer that has a bonding surface after the CMP process with a cross-surface nonuniformity of less than 5%, and/or an aluminum nitride layer that has a full-width-half-maximum (FWHM) of approximately 2 degrees or less after deposition.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method of bonding aluminum nitride in accordance with some embodiments of the present principles.

FIG. 2 depicts a cross-sectional view of an aluminum nitride layer deposited on a substrate in accordance with some embodiments of the present principles.

FIG. 3 depicts a cross-sectional view of an aluminum nitride layer composed of a first aluminum nitride layer and a second aluminum nitride layer deposited on a substrate in accordance with some embodiments of the present principles.

FIG. 4 depicts an aluminum nitride layer undergoing chemical mechanical planarization to form a bonding surface in accordance with some embodiments of the present principles.

FIG. 5 depicts a graph of a nonuniformity measurement of a bonding surface of an aluminum nitride layer in accordance with some embodiments of the present principles.

FIG. 6 depicts a graph of rocking curves across a bonding surface of aluminum nitride layers in accordance with some embodiments of the present principles.

FIG. 7 depicts a cross-sectional view of an aluminum nitride bonding surface being bonded to another substrate in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods provide a high-quality bonding surface for an aluminum nitride film with minimal impact to the thermal conductance performance of the aluminum nitride. The present techniques provide for integration of a high crystallinity, high purity, highly resilient, lower defectivity, and ultimately smoother aluminum nitride film by way of oxygen introduction at an initial deposition stage. The improved, highly resilient aluminum nitride film enables chemical mechanical planarization (CMP) of the aluminum nitride to improve bonding performance. The present techniques allow the aluminum nitride film to not only be formed on silicon but also on silicon containing semiconductor structures due to the process's low temperatures. Thus, the present processes provide for the integration of additional process steps for further planarization, smoothing, defectivity reduction, and bonding improvements. The present techniques also provide improved cross wafer non-uniformity using a low temperature process to produce highly crystalline aluminum nitride on substrate materials such as, but not limited to, silicon (100) substrate material. The processes have a low thermal conductivity penalty and produce a highly crystalline aluminum nitride with high thermal conductivity. The present techniques achieve a bonding layer film using deposition plus CMP processes without additional film integrations or treatments.

Films, such as aluminum nitride, may play pivotal roles in device integration within high performance computing (HPC) chip manufacturing due to such films having improved capability to dissipate heat created within the chips. Aluminum nitride must be crystalline and high purity to maintain a high heat dissipative characteristic, as well as ultra smooth and low in defects to allow for bonding (e.g., wafer-to-wafer bonding, chip-to-wafer bonding, chip-to-chip bonding, etc.). Thus, the manufacturing of such films would require that the film that be deposited with a smooth surface which could be further smoothened through methods such as CMP. However, the inventors have found that pure aluminum nitride film deposited on a silicon substrate does not provide a smooth enough surface for high strength bonding and provides poor resilience (in terms of cross-wafer resistance to planarization processes) to withstand CMP, even with low downforce, and slurry optimizations. CMP processes on aluminum nitride typically result in heavy defectivity while also resulting in significant cross-wafer nonuniformity. Further defectivity reduction with conventional means is not possible without impacting the crystalline quality and cross wafer uniformity of the film and the film's thermal conductance performance.

In contrast, the present techniques produce superior aluminum nitride film that allows for higher CMP downforce, better uniformity, and reduced defectivity through expanded slurry and clean optimization process windows. The present techniques capitalize on the minimal introduction of oxygen during the aluminum nitride deposition to invert the film's polarity from N-polar to Al-polar at the uppermost surface, which is formed into a bonding surface, allowing for almost the entire film thickness to be high purity and high crystallinity aluminum nitride. In some embodiments, the oxygen is introduced during only a portion of the aluminum nitride deposition process. In some embodiments, oxygen is introduced during the entire deposition of the aluminum nitride deposition process. The introduction of the oxygen through the deposition process (e.g., by plasma deposition (physical vapor deposition (PVD)), by chemical deposition (chemical vapor deposition (CVD), atomic layer deposition (ALD), etc.) creates an inversion domain boundary (IDB), thereby flipping the wurtzite structure of the aluminum nitride from an N-polar film to an Al-polar film. The Al-polar film is matched in crystalline structure as well as thermal characteristics to that of an N-polar film but is more resilient to chemical attack on the film's processing surface, enabling control of a CMP process used for improved smoothing and defect removal (e.g., slurry or other surface defects).

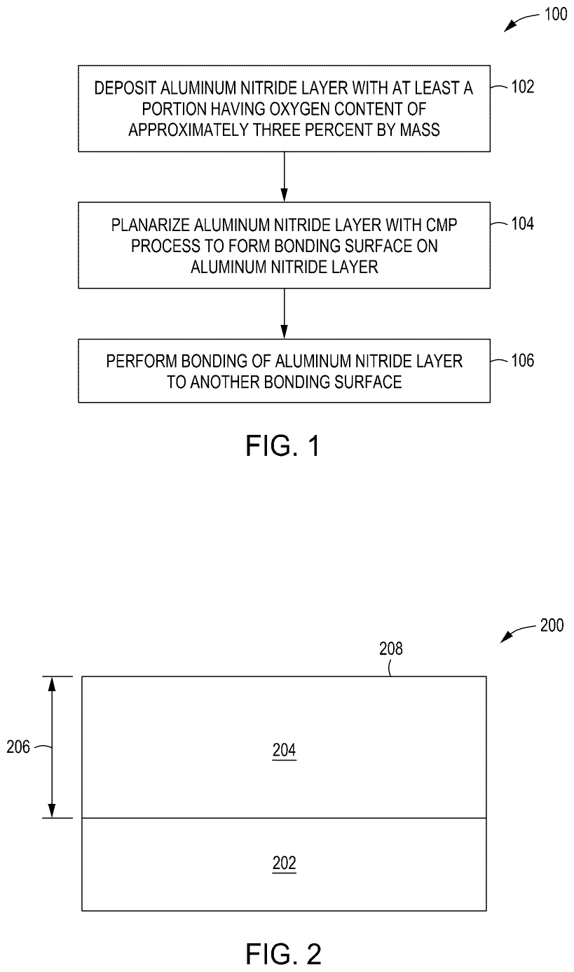

FIG. 1 is a method 100 of bonding aluminum nitride. FIGS. 2-6 may be referenced during the discussion of the method 100. In block 102, an aluminum nitride layer 204 is deposited on a substrate 202 as depicted in a view 200 of FIG. 2. The aluminum nitride layer 204 may be deposited by, but not limited to, PVD, CVD, and/or ALD and the like. The aluminum nitride layer 204 has a thickness 206 that may, for example, be from approximately 100 nm to approximately 1000 nm. A surface 208 of the aluminum nitride layer 204 comprises Al-polar aluminum nitride deposited as per the present methods. In some embodiments, the substrate 202 may be formed of silicon with a crystal structure orientation on the deposition surface of (100). At least a portion of the aluminum nitride layer 204 is deposited with oxygen to yield an oxygen content of approximately 3% by mass for the portion of aluminum nitride deposited with oxygen. In some embodiments, an entire portion of the aluminum nitride layer 204 is deposited with oxygen. In some embodiments, the aluminum nitride deposition process is performed in a process chamber using pulsed RF power.

RF power density on the target area (e.g., substrate surface on which the aluminum nitride is deposited) during deposition of the aluminum nitride layer 204 may range from approximately 5 watts per cm² to approximately 40 watts per cm². In some embodiments, a mixture of argon and nitrogen gas may be flowed into the process chamber at a ratio of argon to nitrogen of approximately 1:3 to approximately 1:5 throughout the aluminum nitride deposition process (with or without oxygen). The process chamber pressure during the deposition of the aluminum nitride is maintained at approximately 2 mTorr to approximately 50 mTorr at a temperature of approximately 250 degrees Celsius or higher. In some embodiments, the temperature is approximately 250 degrees Celsius to approximately 400 degrees Celsius. In some instances, the silicon may contain semiconductor structures with thermal budgets of 400 degrees or less. The present techniques allow for the process to be performed on such silicon substates without thermally impacting or damaging the underlying semiconductor structures.

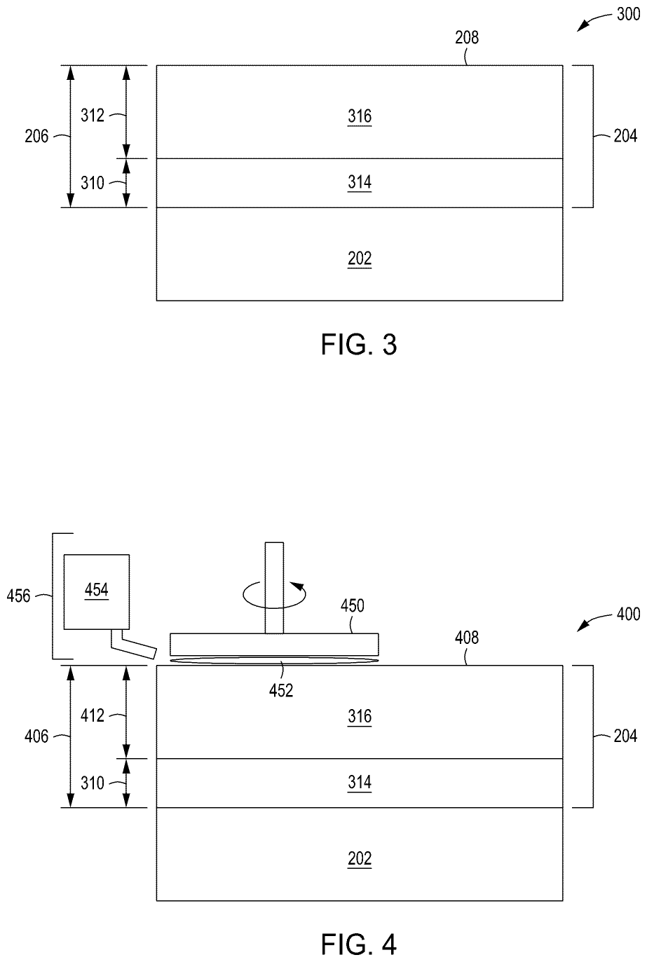

During the portion of the aluminum nitride deposition that is infused with oxygen, approximately 0.5% to approximately 1.5% of oxygen (percent of the total gas mixture by volume) (total gas mixture includes argon, nitrogen, and oxygen) is added into the process chamber during deposition. In some embodiments, the oxygen is only added during deposition of the aluminum nitride during an initial phase of deposition (e.g., a first aluminum nitride layer 314) and then stopped for the remainder of the deposition (e.g., a second aluminum nitride layer 316) as depicted in a view 300 of FIG. 3. The initial phase of deposition may deposit the first aluminum nitride layer 314 with oxygen to a first thickness 310 of approximately 50 nm or less. In some embodiments, the initial phase may deposit the first aluminum nitride layer 314 with oxygen to a first thickness 310 of less than approximately 25 nm. In some embodiments, the initial phase may deposit the first aluminum nitride layer 314 with oxygen to a first thickness 310 of greater than zero to less than approximately 5 nm. The oxygen is introduced to produce an IDB that inverts the aluminum nitride from N-polar (e.g., first aluminum nitride layer 314) to Al-polar (e.g., second aluminum nitride layer 316). The IDB is generally formed within the first aluminum nitride layer 314. The oxygen, in some embodiments, is halted during deposition of the second aluminum nitride layer 316. In some embodiments, the second aluminum nitride layer 316 may have a second thickness of approximately 100 nm to approximately 1000 nm. In such instances, the first aluminum nitride layer 314 is deposited with an oxygen content of approximately 3% by mass and the second aluminum nitride layer 316 is deposited without any oxygen content. In instances where the oxygen is flowed throughout the deposition of the aluminum nitride layer 204, the aluminum nitride layer 204 will have 3% oxygen by mass.

The surface 208 of the aluminum nitride layer 204 that is Al-polar, as per the present methods, has superior resiliency to CMP processing and can be planarized to form a high-quality bonding surface. As per the present methods, the first aluminum nitride layer 314 has a thickness sufficient to enable the formation of the IDB, resulting in the polar inversion of the aluminum nitride deposited thereafter. Limiting the introduction of the oxygen to as thin a layer of aluminum nitride as possible during deposition is beneficial as oxygen in aluminum nitride deposition disrupts the crystal lattice structure of the aluminum nitride and degrades the thermal conductance performance of the aluminum nitride. In the same context, even though lower oxygen infused aluminum nitride layer thickness is desirable, the thermal conductance performance of aluminum nitride, even with infused oxygen, is still substantially superior to other materials such as aluminum oxide and the like in terms of thermal conductance ability. Thus, some embodiments, with oxygen infused throughout the aluminum nitride layer, may still prove beneficial in certain applications. A further benefit is that the aluminum nitride layer 204 produced by the present methods does not require any type of thermal annealing during or after the deposition processes or prior to bonding to improve the crystallinity of the aluminum nitride as is the case for other processes. The lack of required annealing preserves the thermal budgets of any underlying semiconductor structures. In addition, the film deposited by the present techniques using a thin first aluminum nitride layer with oxygen yields aluminum nitride with high crystallinity/alignment which promotes high thermal conductance.

In block 104, the aluminum nitride layer 204 is planarized using a CMP process 456 to form a bonding surface 408 on the aluminum nitride layer 204 as depicted in a view 400 of FIG. 4. The CMP process 456 may be used to remove undulations caused by underlying circuits present before the aluminum nitride deposition and/or to further smoothen the surface for increased bonding performance. Traditional aluminum nitride deposition processes result in a very sensitive film that is substantially removed during the CMP process due to the film's low resiliency, yielding poor film center-to-edge uniformity of the substrate (film completely removed in edge regions during CMP processing). The inventors have found that even with chemical adjustments (e.g., chemistry and pH adjustments, etc.) and mechanical adjustments (e.g., near zero down force, etc.) traditionally formed aluminum nitride film is still eroded heavily by the CMP process, making the use of such aluminum nitride impractical for bonding purposes.

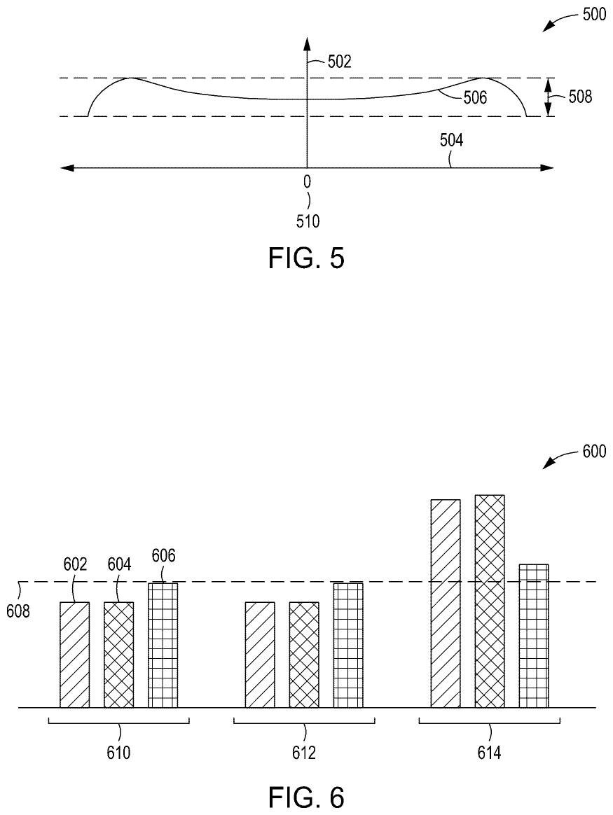

Solely for the sake of brevity, the example of FIG. 4 is depicted with an aluminum nitride layer 204 having a first aluminum nitride layer 314 and a second aluminum nitride layer 316. An aluminum nitride layer 204 as depicted in the view 200 of FIG. 2 may also undergo the CMP process as depicted in FIG. 4. The CMP process 456 may utilize a mechanical rotating pad 450 in conjunction with a slurry 452 on the surface of the aluminum nitride layer 204 to produce the bonding surface 408. The slurry 452 may be provided by a chemical slurry deposition device 454. The chemicals used in the slurry 452 in conjunction with the rotation and downforce of the mechanical rotating pad 450 control the etch rate and aid in the uniformity of the CMP process 456. During the CMP process 456, the second thickness 312 is reduced to a third thickness 412 of the second aluminum nitride layer 316 which also reduces the thickness 406 of the aluminum nitride layer 204. The aluminum nitride layer 204, as deposited by the present techniques, produces a highly resilient surface that can be planarized to produce a smoother surface with greater bonding adhesion capabilities that results in fewer defects and higher bonding yields without increased processing times (oxygen is added in conjunction with aluminum nitride deposition) and with minimal cost increases. The nonuniformity (NU %), in some embodiments, may be less than 5% across the bonding surface 408 of the aluminum nitride layer 204 after planarization as depicted in a graph 500 of FIG. 5. In the graph 500, the Y-axis 502 indicates a height of a surface of the aluminum nitride layer and the X-axis 504 indicates the distance from a center 510 of a substrate and extends radially outwardly in the left and right directions. A line 506 is an example of the bonding surface 408 of the aluminum nitride layer 204 after the CMP process 456. The surface height variations of the bonding surface 408 indicated by the line 506 depict a surface nonuniformity 508 of less than 5% over the substrate surface.

The present techniques produce not only resilient surfaces for aluminum nitride CMP processing but also maintain high-quality crystallinity within the deposited aluminum nitride layer 204 that is necessary for high performance thermal conductance. Graphs 600 of FIG. 6 depict rocking curves for a pure aluminum nitride deposition process 610, a partial oxygen aluminum nitride deposition process of the present techniques 612, and an entire oxygen aluminum nitride deposition process of the present techniques 614. The first bar 602 of each graph denotes full-width-half-maximum (FWHM) of x-ray rocking curves in degrees for a center area of a substrate, the second bar 604 denotes FWHM of x-ray rocking curves in degrees for a middle area radially outwardly from the center area of the substrate, and the third bar 606 denotes FWHM of x-ray rocking curves in degrees for a peripheral area of the substrate. The pure aluminum nitride deposition process 610 does not produce a resilient surface that can withstand further processing by CMP but is shown to indicate the optimal crystalline performance that is obtainable for the best thermal conductance performance of an aluminum nitride film. Dashed line 608 indicates a FWHM of approximately 2 degrees. As depicted by the partial oxygen aluminum nitride deposition process of the present techniques 612, the average FWHM across the substrate surface is less than approximately 2 degrees and is closely inline with the pure aluminum nitride deposition process 610 while permitting additional CMP processing to increase bonding performance. The entire oxygen aluminum nitride deposition process of the present techniques 614 has an average FWHM greater than 2 degrees but still possesses thermal conductance performance substantially greater than other materials such as aluminum oxides and the like.

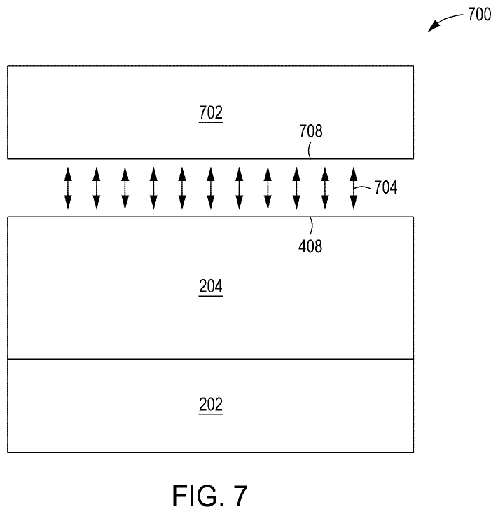

In block 106, the aluminum nitride layer 204 is bonded 704 to another bonding surface 708 of another substrate 702 as depicted in a view 700 of FIG. 7. The enhanced surface provided by the present methods yields a superior bonding surface for the aluminum nitride without requiring pre-bonding annealing while substantially preserving the thermal conductance performance of the aluminum nitride.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method of bonding aluminum nitride, comprising:
depositing an aluminum nitride layer, wherein at least a portion of a thickness of the aluminum nitride layer is deposited with an oxygen content of approximately three percent by mass; and
planarizing the aluminum nitride layer with a chemical mechanical planarization (CMP) process immediately after depositing the aluminum nitride layer and prior to a bonding process to form a bonding surface.

2. The method of claim 1, wherein the at least a portion of the thickness is approximately 5 nm to approximately 50 nm and the thickness is approximately 100 nm to approximately 1000 nm.

3. The method of claim 1, wherein the aluminum nitride layer is deposited on a silicon material with a crystal structure orientation on a deposition surface of (100).

4. The method of claim 3, wherein the silicon material contains at least one semiconductor structure.

5. The method of claim 1, wherein the aluminum nitride layer is deposited at a temperature of approximately 250 degrees Celsius to approximately 400 degrees Celsius.

6. The method of claim 1, wherein the aluminum nitride layer is deposited using RF with a power density of approximately 5 watts per cm² to approximately 50 watts per cm².

7. The method of claim 1, wherein argon and nitrogen are present during deposition of the aluminum nitride layer in an argon to nitrogen ratio of approximately 1:3 to approximately 1:5.

8. The method of claim 1, wherein oxygen used during deposition of at least a portion of the aluminum nitride layer is approximately 0.5 percent to approximately 1.5 percent of gases by volume used during deposition.

9. The method of claim 1, wherein the aluminum nitride layer is deposited in a process chamber using pulsed RF power.

10. The method of claim 1, wherein the aluminum nitride layer has a bonding surface after the CMP process with a cross-surface nonuniformity of less than 5%.

11. The method of claim 1, wherein the aluminum nitride layer has a full-width-half-maximum (FWHM) of approximately 2 degrees or less after deposition.

12. A method of bonding aluminum nitride, comprising:
depositing a first aluminum nitride layer with an oxygen content of approximately three percent by mass on a silicon material with a crystal structure orientation on a deposition surface of (100), wherein the first aluminum nitride layer has a first thickness of approximately 5 nm to approximately 50 nm;
depositing a second aluminum nitride layer without oxygen on the first aluminum nitride layer, wherein the second aluminum nitride layer has a second thickness of approximately 100 nm to approximately 1000 nm; and
planarizing the second aluminum nitride layer with a chemical mechanical planarization (CMP) process to form a bonding surface immediately after depositing the second aluminum nitride layer and prior to a bonding process.

13. The method of claim 12, wherein the silicon material contains at least one semiconductor structure.

14. The method of claim 12, wherein the first aluminum nitride layer and the second aluminum nitride layer are deposited at a temperature of approximately 250 degrees Celsius to approximately 400 degrees Celsius.

15. The method of claim 12, wherein the first aluminum nitride layer and the second aluminum nitride layer are deposited using RF with a power density of approximately 5 watts per cm² to approximately 50 watts per cm².

16. The method of claim 12, wherein oxygen used during deposition of the first aluminum nitride layer is approximately 0.5 percent to approximately 1.5 percent of gases by volume used during deposition of the first aluminum nitride layer.

17. The method of claim 12, wherein the second aluminum nitride layer has a bonding surface after the CMP process with a cross-surface nonuniformity of less than 5%.

18. The method of claim 12, wherein the first aluminum nitride layer and the second aluminum nitride layer combined has a full-width-half-maximum (FWHM) of approximately 2 degrees or less after deposition.

19. A non-transitory, computer readable medium having instructions stored thereon that, when executed, cause a method of bonding aluminum nitride to be performed, the method comprising:
depositing an aluminum nitride layer, wherein at least a portion of a thickness of the aluminum nitride layer is deposited with an oxygen content of approximately three percent by mass; and
planarizing the aluminum nitride layer with a chemical mechanical planarization (CMP) process immediately after depositing the aluminum nitride layer and prior to a bonding process to form a bonding surface.

20. The non-transitory, computer readable medium of claim 19, wherein the method further comprises at least one of (a), (b), (c), (d), (e), (f), and (g):
(a) wherein the at least a portion of the thickness is approximately 5 nm to approximately 50 nm and the thickness is approximately 100 nm to approximately 1000 nm;
(b) wherein the aluminum nitride layer is deposited on a silicon material with a crystal structure orientation on a deposition surface of (100) and wherein the silicon material contains at least one semiconductor structure;
(c) wherein the aluminum nitride layer is deposited at a temperature of approximately 250 degrees Celsius to approximately 400 degrees Celsius;
(d) wherein the aluminum nitride layer is deposited using RF with a power density of approximately 5 watts per cm² to approximately 50 watts per cm²;
(e) wherein oxygen used during deposition of at least a portion of the aluminum nitride layer is approximately 0.5 percent to approximately 1.5 percent of gases by volume used during deposition;
(f) wherein the aluminum nitride layer has a bonding surface after the CMP process with a cross-surface nonuniformity of less than 5%; or
(g) wherein the aluminum nitride layer has a full-width-half-maximum (FWHM) of approximately 2 degrees or less after deposition.
